(19) United States
(12) Patent Application Publication
(10) Pub. No.: US 2026/0203487 A1
(43) Pub. Date: Jul. 16, 2026

(54) METHOD FOR AUTOMATED CLASSIFICATION OF DEFECTS OF PHOTOLITHOGRAPHIC MASKS

(71) Applicant: Carl Zeiss SMT GmbH, Oberkochen (DE)

(72) Inventors: Michael Niebisch, Jena (DE); Alexander Freytag, Erfurt (DE); Bjoern Froehlich, Jena (DE); Bjoern Brauer, Magstadt (DE); Anka Birnstein, Dresden (DE)

(21) Appl. No.: 19/450,210

(22) Filed: Jan. 15, 2026

(30) Foreign Application Priority Data
Jan. 16, 2025 (DE) 102025101389.6

(51) Int. Cl. G06F 30/3308

(52) U.S. Cl. CPC G06F 30/3308

(57) ABSTRACT

The invention relates to a method for user-side training of an artificial intelligence for automated classification of defects on photolithographic masks on the basis of an aerial image of a photolithographic mask and to a method for using the artificial intelligence trained thus. The artificial intelligence is trained on the basis of defect candidates identified on an aerial image and simulated defect candidates generated on the basis thereof according to existing rules. By combining at least the identified defect candidates into defect groups, it is possible to greatly reduce the effort of the user during the training. The artificial intelligence is applied on the basis of a captured aerial image, wherein defect candidates can be identified on the basis thereof and can subsequently be classified by the artificial intelligence trained according to the invention.

### CROSS-REFERENCE TO RELATED APPLICATION

This application claims benefit under 35 U.S.C. §119 to German Patent Application 102025101 389.6, filed on January 16, 2025, the entire content of which is incorporated herein by reference.

### TECHNICAL FIELD

The invention relates to a method for user-side training of an artificial intelligence for automated classification of defects on photolithographic masks on the basis of an aerial image of a photolithographic mask and to a method for using the artificial intelligence trained thus.

### BACKGROUND

Photolithography is used for producing microstructured components, such as for example, integrated circuits. The photolithography process is carried out in what is known as a projection exposure apparatus, which comprises an illumination device and a projection device. The image of a mask (also called “reticle”) illuminated by use of the illumination device is projected in this case by use of the projection device onto a substrate, for example, a silicon wafer, that is coated with a light-sensitive layer (so-called “photoresist”) and arranged in the image plane of the projection device in order to transfer the mask structure to the light-sensitive coating of the substrate. In subsequent production steps, the transferred structure is implemented in the substrate, e.g., by etching.

Even if the projection devices of projection exposure apparatuses have a reduction factor of, e.g., 8:1, the structures of the masks already need to have a high accuracy owing to the advancing miniaturization in the semiconductor field and the transition in the wavelength during exposure from DUV (e.g., 193 nm) to the EUV (e.g., 13.5 nm). In order to ensure that a mask satisfies these quality requirements and a microstructured component produced thereby also has the desired properties and functioning mode, a mask is checked for deviations from the structure actually desired by use of suitable methods before use in a projection exposure apparatus.

Mask inspection devices have been developed to carry out this check. Such devices can be used to inspect masks prior to operation in a microlithographic projection exposure apparatus or during an operational interruption in order to detect possible faults or impurities that may lead to a rejection of semiconductors manufactured on the basis of the mask. For this purpose, one or more so-called aerial images of in each case one section of the photomask are generated, which can be examined for faults and impurities. In general, the term “aerial image” is understood in this context to mean the intensity distribution in the image plane of an optical system. To generate the aerial images, the mask is exposed to radiation at a suitable wavelength by an illumination system and the radiation transformed by the mask is imaged by an optical unit having one or more optical elements onto an image sensor which is suitable for the selected wavelength and situated in an image plane. In optical systems having a plurality of image planes, a corresponding number of aerial images can be defined as required, or an aerial image has a corresponding number of dimensions or planes.

The aerial images thus obtained are subsequently examined for potential defects. In doing so, potential defects can be located purely by analyzing the aerial images, for example, by identifying unusual structures or defects or by way of a comparison with a reference, e.g., with a “target aerial image” which shows the desired defect-free mask.

A potential defect must subsequently be classified. Within the scope of this classification, the type of defect is determined, and its effects on a microstructured component produced using the mask is evaluated. While the type of defect may provide information about its source in the production and handling process of the mask and/or information regarding the removal thereof, the assessment of the effects of a defect results in the imperative to remove the defect or — should repair not be possible — to consider the mask as a reject.

In the prior art, this classification is carried out by staff trained in this respect, wherein the classification by staff trained in this respect may be supported by individual aids implemented on a computer. However, it was found that extensive automation of the classification of potential defects of photolithographic masks already fails in principle owing to the fact that manufacturers of microstructured components apply extremely individual criteria for assessing potential defects, and these cannot be combined into a common framework, for example, by the manufacturer of mask inspection devices. As a consequence, each potential defect is classified on an individual basis by said trained staff, and this is very time-consuming and requires a lot of resources.

Moreover, especially the evaluation of the effects of a mask defect on a microstructured component produced using this mask depends on the experience of the member of staff and can lead to a variety of outcomes. Thus, the known method may be subject to the risk of subjective incorrect evaluation.

### SUMMARY

The problem addressed by the present invention is that of developing a method in which the disadvantages from the prior art no longer occur or occur only to a reduced extent.

This problem can be solved by a method according to Claim 1. The dependent claims relate to advantageous developments.

Accordingly, the invention relates to a method for user-side training of an artificial intelligence for automated classification of defects on photolithographic masks on the basis of an aerial image of a photolithographic mask, including the steps of:

a) identifying defect candidates on the aerial image;

b) combining the identified defect candidates to form defect groups;

c) querying the classification of the defect candidates and/or defect groups from a user, for which purpose the defect candidates and/or at least one defect candidate representative of a defect group is displayed to the user;

d) generating simulated defect candidates by modifying the classified defect candidates according to rules that exist for a respective classification;

f) training the artificial intelligence using the classified defect candidates and classified simulated defect candidates for automated classification of a defect candidate not classified by a user.

In this document, the phrase “artificial intelligence” broadly refers to an artificial intelligence model, artificial intelligence classifier, a machine learning model, a machine learning classifier, or an artificial intelligence or machine learning system that includes an artificial intelligence or machine learning model or classifier. The phrase “training the artificial intelligence” broadly refers to training an artificial intelligence model, an artificial intelligence classifier, a machine learning model, a machine learning classifier, or an artificial intelligence or machine learning system that includes an artificial intelligence or machine learning model or classifier. The invention also relates to a method for automatically classifying defects on photolithographic masks on the basis of an aerial image of a photolithographic mask, comprising the steps of:

a) identifying defect candidates on the aerial image; and

b) using the artificial intelligence trained using the method according to the invention to classify the identified defect candidates.

The invention renders usable an artificial intelligence in order to be able to perform the classification of defects on photolithographic masks in (partially) automated fashion, so as to achieve a rapid and less error-prone classification of potential defects. In this context, the invention has identified that general training of an artificial intelligence for the classification of defects on photolithographic masks may be difficult or in some scenarios not possible owing to application-specific and user-specific requirements and the lack of availability of relevant training data on account of high confidentiality. Instead, an application-specific and/or user- specific artificial intelligence can be trained on the basis of a limited number of potential training data sets in order to be able to rapidly at least partially automate the classification of potential defects.

In this case, the method according to the invention is based on an aerial image of a photolithographic mask. In this context, the aerial image may have been created by any known mask inspection device. To create an aerial image, the photolithographic mask is exposed — as a rule section by section — using the same exposure settings and the same wavelength as will later be used in the actual photolithographic process. In contrast to photolithography, where the mask structure is imaged with a reduced size onto a substrate, the mask structure is enlarged and imaged onto an image capture sensor and stored digitally for the purpose of generating an aerial image. The aerial image composed from the sections or from the captured images thus corresponds to the image or the corresponding section that would be generated on the substrate under production conditions in a projection exposure apparatus.

The aerial image can be generated in different ways, for example, by use of an imaging method. For example, suitable imaging methods may comprise: the application of a particle beam system such as a scanning electron microscope (SEM), a focused ion beam microscope (FIB) or an atomic force microscope (AFM), the application of an aerial image measuring system, for example, equipped with a staring array sensor, a line scanning sensor or a time delay integration (TDI) sensor, or the use of a camera adapted to record images at predetermined wavelengths. The camera may be an EUV camera or a camera comprising a TDI sensor. Accordingly, the camera image sensor may be an EUV image sensor, i.e., a sensor which is sensitive to EUV light. Each image sensor can include, e.g., an array of individually addressable sensing elements or pixels. EUV light is light in the extreme ultraviolet spectrum with wavelengths between 5 nm and 100 nm, especially with wavelengths between 5 nm and 30 nm. With particular preference, the EUV light may have a wavelength of 13.5 nm. The EUV camera may be adapted for use in a photolithographic mask inspection system, with the photolithographic mask being projected onto an EUV image sensor of the EUV camera. In preferred embodiments, the imaging method comprises illuminating a photolithographic mask with actinic radiation, the wavelength of which is located within the EUV wavelength range. EUV radiation reflected off the photolithographic mask is then projected onto an image sensor of the EUV camera by use of appropriately adapted projection optics units. In a first step (a), defect candidates are ascertained on the aerial image. “Defect candidates” are locations or regions on the aerial image which potentially represent a defect and must therefore be checked. In this context — for reasons of clarity — both the actual defect candidate and an image section on which the defect candidate can be seen are referred to collectively as the “defect candidate,” with the respective meaning of the term being evident to a person skilled in the art directly from the context. In this case, the image section in question generally also comprises the surrounding structure of the photolithographic mask.

Since the amount of data means that a user can only very theoretically identify defect candidates on an aerial image, the prior art has already disclosed various options for performing a defect candidate identification in automated fashion. For example, defect candidates may be identified by image comparison by virtue of a recorded aerial image or regions thereof being compared with at least one comparison image — specifically, e.g., a previously recorded aerial image or a region thereof of photolithographic masks which are identical in principle or at least in regions — with a deviation indicating a defect candidate on one of the aerial images. In this context, the term “deviation” should be interpreted broadly and relates to all differences arising from the image data to be compared with one another.

Should a photolithographic mask comprise a structure that repeats over a large area, a region of an aerial image of this structure may be compared with another region of the same aerial image as comparison image, with a deviation then indicating a defect candidate in one of the regions compared with each other. It is also possible to compare a recorded aerial image with an image representation generated from the design data of the photolithographic mask, with deviations in that case directly indicating defect candidates on the aerial image. Various methods for generating appropriate image representations from design data are known from the prior art, for example, using a virtual model of the device used to record the aerial image. The desired image representation then corresponds to the imaging of a virtual photolithographic mask, which was generated from the design data, by the virtual model onto the virtual image plane thereof.

The term “deviation” should be interpreted broadly here.

Once the artificial intelligence to be trained using the method according to the invention and yet to be explained in detail below has been trained to a sufficient extent, the identification of defect candidates may preferably also be supported or even carried out by the artificial intelligence: If the training according to the invention of the artificial intelligence has already considered a sufficient number of defect candidates or if the training deliberately or inadvertently comprised a sufficient large number of training sets of defect-free aerial images or regions thereof, then the artificial intelligence is capable of identifying defect candidates or defect-free regions on the aerial image with a sufficient degree of reliability — optionally even without a comparison image being available.

The identification of defect candidates is followed in step (b) by combining the identified defect candidates to form defect groups. In the process, those defect candidates which are similar on account of the image representation of the defect candidates on the aerial image are combined into a group. Naturally, it is also possible that one, multiple or all of the defect groups each comprise only one individual defect candidate, for example, because there is not sufficient similarity between a defect candidate and any other defect candidate.

The comparisons of defect candidates for similarity, which are required for combining identified defect candidates to form defect groups, may be performed using known image analysis or image comparison methods. For example, sizes, shapes or details of the image representation of defect candidates in the aerial image may be captured and compared with one another in automated fashion such that — given sufficient correspondence — defect candidates may be combined to form a defect group.

Once the artificial intelligence to be trained using the method according to the invention and yet to be explained in detail below has been trained to a sufficient extent, the combination of identified defect candidates to form defect groups may preferably also be supported or even carried out by the artificial intelligence: This is because if the artificial intelligence is already capable of ascertaining a first proposal for a potential classification of the defect candidates, then the defect candidates can be grouped on the basis of the classification proposals.

Subsequently, the classification of the defect candidates combined into defect groups is queried from a user. To this end, the defect candidates in a defect group or at least one defect candidate representative of the defect group is displayed to the user. In the process, a selection of potential classifications may also be displayed directly to the user, and said user may choose the suitable one thereof. Naturally, it is also possible that the user supplements the classifications offered with one or more classifications. In this case, the classification may be user-specific and/or application-specific, i.e., the classification offered is not a fixedly predetermined standardized set of classifications. Rather, a user or, e.g., a company may predetermine their individual classification, optionally even for specific types of photolithographic masks.

In order to design the classification of the defect candidates as efficiently as possible for the user, the defect candidates are classified at the level of the defect groups. In other words, the classification for a defect group is queried from the user, and this classification is subsequently applied to all defect candidates contained in the defect group. In the process, the user is preferably able to remove defect candidates which do not fit to the defect group from the defect group in advance, and so the classification performed for the remaining defect group is not applied to defect candidates previously removed from the defect group. In the event of a potentially incorrect assignment of a defect candidate to a defect group, it is thus possible to avoid an incorrect classification of this defect candidate without the user needing to fall back to an individual classification of each individual defect candidate.

The classifications offered to the user preferably also contain classifications which label a defect candidate or a defect group as not containing an actual defect. This also includes those defect candidates in which apparent defects are merely imaging effects within the scope of the aerial image capture which act like defects. Such a classification allows the artificial intelligence to be improved in view of the identification of defect candidates on the aerial image — provided it is used to this end; see above. Additionally, the subsequent steps for classified defect candidates may be omitted for defect candidates from precisely this classification, and this reduces not only the need for computing power but also the outlay required by the user.

Once the artificial intelligence to be trained using the method according to the invention and yet to be explained in detail below has been trained to a sufficient extent, querying of the classification of the identified defect candidates from a user may preferably also be supported by the artificial intelligence: Thus, when querying the classification, the artificial intelligence may already propose to the user the classification assessed as the most likely by the artificial intelligence. It is essential that even if the artificial intelligence is capable of supporting the classification, the ultimate confirmation as regards the classification a defect group should be assigned is carried out by the user. Only this ensures that the artificial intelligence is trained rapidly in a targeted manner.

On the basis of the classification queried from the user, simulated defect candidates are then generated on the basis of the classified defect candidates by virtue of the available defect candidates being modified on the basis of rules which exist for the respective classification. The rules which exist for the individual classifications and can and should be used to modify the defect candidates in the corresponding classification in order to generate a plurality of simulated defect candidates may overlap for the individual classifications or even be partially identical. However, by virtue of there being classification-specific rules as a matter of principle, modifications that lead to useful simulated defect candidates for a defect candidate in a specific classification but are not useful for defect candidates in other classifications can remain restricted to the relevant defect candidates.

The modifications for obtaining simulated defect candidates may comprise image-related modifications to the defect candidate or to the recording thereof, for example, modifications to the brightness and/or contrast, scaling and/or rotating the entire recording, the addition or reduction of noise, etc. In an alternative to that or in addition, the modifications may also comprise motif manipulations, i.e., the manipulation of the actual defect candidate, while the surrounding structure imaged in addition to the actual defect candidate remains unchanged in principle. Thus, the actual defect candidate may be modified in isolation from the surrounding structure, e.g., by scaling, translation and/or rotation. The motif manipulation also includes isolating the potential defect in the image from a defect candidate and then copying said potential defect onto another region of the aerial image which is actually defect free, i.e., consequently modifying the photolithography structure surrounding the potential defect.

The rules which form the basis for the modification of the classified defect candidates in order to generate simulated defect candidates are adapted in view of the querying of the classification of the simulated defect candidates, which takes place in the next step. For example, if an existing rule stipulates that the contrast may be reduced by up to 50% for a classified defect candidate but correspondingly simulated defect candidates with a 50% reduced contrast are regularly analyzed as not being identical to the underlying classified defect candidate whereas defect candidates with only 40% reduced contrast are analyzed as identical, then the rule may be adapted for the affected classification in such a way that in future the contrast is only reduced by a maximum of 40%. It is self-evident that confidence requirements may be provided here for the adaptation of a rule. It is also possible to provide for the ranges specified by the rules, e.g., as regards the reduction in contrast, to be occasionally exceeded by a small amount in order to thereby test whether the existing rules continue to be plausible. The described adaptation of the existing rules for the modification of the classified defect candidates in order to generate simulated defect candidates may be performed with the aid of an artificial intelligence, or the latter may at least support this, wherein the artificial intelligence used to this end need not be the artificial intelligence to be trained or at least partially trained for classifying defect candidates.

It is also possible for simulated defect candidates to be generated by a generative artificial intelligence on the basis of classified defect candidates.

The respective classification for the simulated defect candidates generated on the basis of the existing rules is queried from the user, for which purpose the defect candidates are displayed to the user. The user may then choose a correct classification for the defect candidate displayed to them.

The classification may be queried on an individual basis for each simulated defect candidate. However, in a manner analogous to querying the classification of the identified defect candidates which were combined to form defect groups, the simulated defect candidates may also be combined to form defect groups. The simulated defect candidates are then displayed to the user in groups, wherein the classification of the simulated defect candidates is queried at the level of the defect groups, wherein simulated defect candidates not matching the defect group can preferably be removed from the defect group by the user. For explanation, reference is made to the statements above.

A proposal for a potential classification may also be submitted to the user in relation to querying the classification of the simulated defect candidates and/or defect groups of defect candidates. The proposal for the classification may emerge from the classification of that identified defect candidate on which the simulated defect candidate to be classified is based. Once the artificial intelligence to be trained using the method according to the invention and yet to be explained in detail below has been trained to a sufficient extent, querying of the classification of the simulated defect candidates from a user may also be supported by the artificial intelligence by virtue of the classification assessed as the most likely by the artificial intelligence being proposed to the user when querying takes place. It is also essential here that independently of how a proposal for the classification is generated, the ultimate confirmation as regards the classification a simulated defect candidate or a group of defect candidates should be assigned is carried out by the user. Only this ensures that the artificial intelligence is trained rapidly in a targeted manner.

In order to be able to reduce the outlay for the user even further, it is preferable for the classification not to be queried at least for simulated defect candidates (optionally also for defect candidates identified on the aerial image) which promise no or only a small learning effect for the artificial intelligence. Should the classification of a certain type of defect candidate already be trained to such a sufficient extent, a classification of a defect candidate of precisely this type by the user will regularly have no effect or only very slight effect on the classification accuracy of the artificial intelligence to be trained. In cases in which a large number of identified or simulated defect candidates are available in principle, it may be advantageous for the user to query the classification only of that portion of the defect candidates in which a significant “learning effect” for the artificial intelligence can be assumed.

Once the classification of the simulated defect candidates is completed, simulated defect candidates, each of which were classified by the user, are available in addition to the identified defect candidates. Hence, an amount of training data verified by the user which exceeds the number of defect candidates actually originally identified in the aerial image is available — specifically an amount increased by the number of simulated defect candidates. In this context, the method according to the invention ensures that even in the case of a possibly limited number of identified defect candidates, an increased amount of training data is available, but the outlay for the user in terms of the classification generally remains manageable.

All defect candidates classified in the method, whether simulated or identified in the aerial image, are subsequently used to train one of the artificial intelligences for automated classification of a defect candidate not classified by a user. By virtue of providing an artificial intelligence with training data containing defect candidates and the associated classification, the artificial intelligence can be trained in order to independently perform, at a later time (after receiving a sufficient amount of training data), a defect candidate classification for a defect candidate not classified by a user.

Especially if the artificial intelligence to be trained using the method according to the invention has already been used in one of the preceding steps to identify defect candidates, defect candidates on the aerial image may be identified anew on the basis of the previously obtained training data following the completed training. The aerial image is an aerial image that was already analyzed previously; however, on account of the artificial intelligence having been subjected to further training it is possible that defect candidates not previously detected as such are identified. Should new defect candidates be in fact identified, the steps explained above up to and including the training of the artificial intelligence can be performed for these newly identified defect candidates.

Even if the method according to the invention serves the user-specific and/or application-specific training of the artificial intelligence, the artificial intelligence may have been initially trained using a user-unspecific and/or application-unspecific basic training data set — especially for the case that the at least partially trained artificial intelligence should be used in any of the steps of the method. By virtue of the artificial intelligence being trained using an appropriate basic training data set, the artificial intelligence may already be used for various tasks during the first iteration of the method. The possibly complex provision of alternative algorithms for tasks that should be carried out at a later time by an at least partially trained artificial intelligence may thus be dispensed with. The basic training data set should preferably be designed such that it biases the artificial intelligence as little as possible, or a possible initial bias is overridden as quickly as possible by the training according to the invention. The artificial intelligence may also be designed to discard the basic training data as soon as sufficient training data is available from the method according to the invention.

It is preferable for at least one artificial intelligence or at least a part of an artificial intelligence to be based on an algorithm for machine learning, preferably random decision forests or k-nearest neighbour, or an algorithm for deep learning, preferably convolutional neural networks or vision transformer networks. It is also possible to resort to diffusion models. The corresponding algorithms are known from the prior art for applications other than the one present but can in principle also be transferred to the present application by a person skilled in the art.

As regards the explanation of the method according to the invention for automatically classifying defects on photolithographic masks on the basis of an aerial image of a photolithographic mask, reference is made to the statements above.

If an artificial intelligence (fully) trained according to the invention is provided with a defect candidate from an aerial image, the artificial intelligence can undertake the correct classification of the defect candidate with a reliability that is at least comparable to that of a human user. For example, an artificial intelligence model is generally considered fully trained if the errors it makes are below a prescribed threshold.

In principle, the defect candidate may be identified on the aerial image in any desired manner. However, it is preferable for the artificial intelligence trained according to the invention to be used to identify defect candidates on an aerial image. Reference is made to the corresponding explanations given in relation to the identification of defect candidates on the aerial image by the artificial intelligence — only partially trained in that case — within the scope of the method for the user-side training of the artificial intelligence.

The photolithographic mask may have an aspect ratio between 1:1 and 1:3, preferably between 1:1 and 1:2 and particularly preferably of 1:1 or 1:2. The photolithographic mask may be configured in substantially rectangular fashion. The photolithographic mask may preferably be 12.7 cm (5 inches) to 17.8 cm (7 inches) long and wide, preferably 15.2 cm (6 inches) long and wide. As an alternative thereto, the photolithographic mask may be 12.7 cm (5 inches) to 17.8 cm (7 inches) long and 25.4 cm (10 inches) to 35.6 cm (14 inches) wide, preferably 15.2 cm (6 inches) long and 30.5 cm (12 inches) wide.

### BRIEF DESCRIPTION OF THE DRAWINGS

The invention will now be described by way of example on the basis of an advantageous embodiment with reference to the accompanying drawings, in which:

FIG. 1: shows a schematic illustration of a method according to the invention for user-side training of an artificial intelligence for automated classification of defects on photolithographic masks on the basis of an aerial image of a photolithographic mask; and

FIG. 2: shows a schematic illustration of a method for automatically classifying defects on photolithographic masks on the basis of an aerial image of a photolithographic mask.

### DETAILED DESCRIPTION

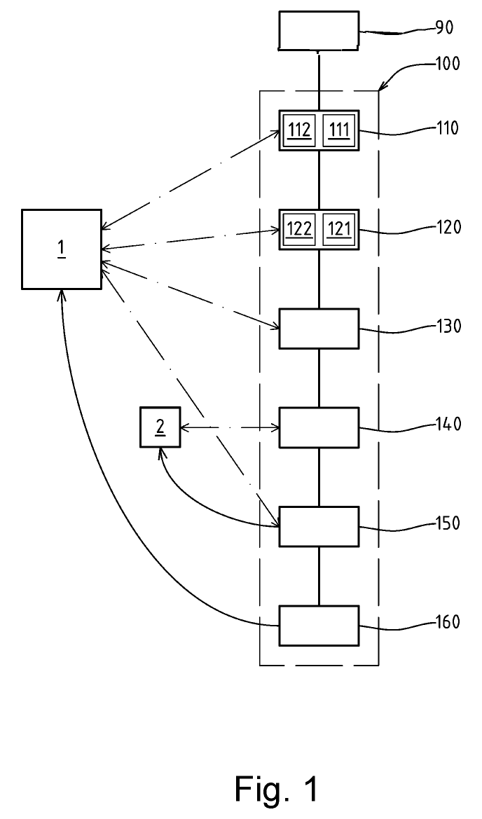

FIG. 1 schematically shows an exemplary embodiment of a method 100 according to the invention for user-side training of an artificial intelligence 1 for automated classification of defects on photolithographic masks on the basis of an aerial image of a photolithographic mask. For example, the artificial intelligence model 1, or at least a part of the artificial intelligence model 1, can be based on an algorithm for machine learning, preferably random decision forests or k-nearest neighbour, or an algorithm for deep learning, preferably convolutional neural networks or vision transformer networks. It is also possible to use to diffusion models.

The method 100 is based on one or more aerial images of one or more photolithographic masks, which are acquired in a preparatory step 90, which is not part of the actual method 100, with the aid of suitable mask inspection devices. Since corresponding devices and acquisition methods are sufficiently well known in the prior art, explanations in this regard may be omitted here.

The one or more aerial images acquired thus are then supplied to the method 100 according to the invention. In a first step 110, defect candidates are identified on the at least one aerial image by virtue of searching the aerial images for regions on which possible defects are imaged. To this end, two different methods 111, 112 are applied in parallel in the exemplary embodiment illustrated.

In the first method 111, the respective aerial image to be examined is compared with an image representation created from the design data relating to the photolithographic mask imaged on the aerial image and possible differences that exceed a predetermined measure for a still permissible deviation are identified as defect candidates. An example of a permissible deviation is a deviation of the aerial image from the created image representation that is still acceptable on the mask. For example, the width of a structure or a gap between might be smaller than actually intended and designed, but still in a range that will allow a chip to be produced with the mask to properly function.

In the second method 112, use is made of the artificial intelligence 1 to be trained using the method 100. Should the artificial intelligence 1 already have been subjected to initial training by virtue of already having run through the method 100 according to the invention a few times or by virtue of being subjected to rudimentary training on the basis of a basic training data set provided to this end, it is able to search on an aerial image for regions in which, at the current state of training, it would propose a classification for a defect with a probability above a predetermined value. The potential defect found in this way then is a defect candidate. Should the artificial intelligence 1 not yet have been trained to a sufficient extent when running through the method 100, the application of the method 112 based thereon may be omitted.

Irrespective of the method with which they were identified, the defect candidates are then transferred to the next step 120, with duplications of defect candidates that were found in both methods being avoided.

The identified defect candidates are combined to form defect groups in step 120. Two different methods 121, 122 are also provided to this end; however, they are not applied in parallel but exclusively in each case.

Groups are formed by automated image comparison in the method 121. To this end, the defect candidates, more precisely the sections of the aerial image with the individual defect candidates, are examined for similarities using known image analysis methods. For example, if foreign particles are situated on a photolithographic mask whose aerial image was supplied to the method 100, then the individual foreign particles may be identified as defect candidates, wherein the associated image representations may be distinguished by a relatively large continuous region with specific shading. Automated image comparisons allow defect candidates with corresponding characteristics to be combined to form a defect group.

In an alternative to that, the artificial intelligence 1 already trained to a sufficient extent may ascertain a proposal for the classification of each of the defect candidates in the method 122, wherein those defect candidates for which the artificial intelligence 1 has ascertained the same proposal for a classification are combined in a defect group in that case.

In order to avoid an assignment conflict, the method 100 provides for the identified defect candidates to be combined to form defect groups using the method 121 until the artificial intelligence 1 has been trained to a sufficient extent to enable an improved assignment to defect groups in comparison with the method 121. In this case, only the method 122 is applied subsequently.

Subsequently, in step 130, the identified defect candidates are displayed to the user grouped in defect groups in order to be classified by said user.

To this end, all identified defect candidates of a defect group are displayed to the user, and a list of possible classifications, which may be supplemented by the user if necessary, is provided for selection. In some implementations, defect classes can be specific for different workflows and users, and some of the defect classes can be adapted to each new use case. In the process, the user can quickly check whether any of the identified defect candidates displayed to them is possibly incorrectly assigned to the defect group determined by the other defect candidates and can subsequently remove it from the defect group. Subsequently, they may specify the suitable classification for the remaining identified defect candidates in the defect group by virtue of selecting it from the proposed classifications (optionally supplemented by the user), wherein the classifications for “non-identifiable” or “no defect” may also be provided. For example, the “non-identifiable” classification may be assigned to defect candidates that the user can neither identify the defect candidate to clearly belong to a specific classification or be a “non-defect”. For example, this may be due to blurring, lack of contrast, etc. For example, the “no defect” classification may be assigned to defect candidates that are determined by the user to be non-defects, e.g., the apparent defects are merely imaging effects within the scope of the aerial image capture which act like defects. In this context, the chosen classification is assigned to each defect candidate remaining in the defect group, and so the classification is ultimately carried out at the defect group level. Once the defect candidates in a defect group have been classified, the next defect group is displayed to the user for classification until all defect groups or the defect candidates contained therein are classified.

Should the artificial intelligence 1 already be trained to a sufficient extent, the artificial intelligence 1 can also provide the user with a proposal for the suitable classification. Should the identified defect candidates have been combined according to method 122 in step 120, the classification forming the basis for the formation of the defect group in that case may be submitted to the user as a proposal. However, it should be noted that the actual classification is in fact carried out by the user in all cases, even when proposals are submitted by the artificial intelligence 1.

In the next step 140, simulated defect candidates are generated on the basis of the previously classified identified defect candidates — at least of those that were not classified as “non-identifiable” or “no defect.” In the process, the classified identified defect candidates are modified in accordance with rules which exist for the respective classification, with the basic aim being that even the defect candidates simulated in this way are able to be assigned to the same classifications as the respective underlying identified defect candidate. Examples of the rules can include change of contrast, change of size, and change of aspect ratio. In an alternative to that or in addition, individual modifications may also be made in such a way that a simulated defect candidate might “just no longer” be assignable to the classification of the underlying identified defect candidate (e.g., the original defect is over a certain threshold that qualifies it as a defect, but the simulated “defect” is just below the threshold so that it may be classified a “non-defect”), whereby the artificial intelligence may later be able to make a sharper distinction between defect and non-defect.

The modifications of the identified defect candidates in order to obtain simulated defect candidates comprise image modifications and motif manipulations, i.e., changes in the brightness and/or contrast, the scaling and/or rotation of the entire recording, the addition or reduction of noise, the modification of the actual defect candidate by scaling, translation and/or rotation in a manner isolated from the surrounding structure.

In this case, there are fundamentally different rules for the modifications to the identified defect candidates between the various classifications in order to come close the basic objective of creating simulated defect candidates with the same classifications as the respective underlying identified defect candidate. Since certain modifications achieve this objective in the case of defect candidates from a certain classification but the same modifications do not result in a suitable simulated defect candidate in the case of other classifications, it is advantageous to provide the rules for the modifications on an individual basis for the individual classifications even if there may be far-reaching overlaps between the respective rules, in part up to identity. For example, while most of the rules may just be overlapping in parts, even large parts, some rules may be identical.

Incidentally, the existing rules may also be optimized with the aid of the further artificial intelligence 2. Hence, the results from the following step 150 concerning the query of the classification of the simulated defect candidates may be used to adapt the existing rules if required, specifically in such a way that, in particular, simulated defect candidates which are not assigned to the same classification as the underlying identified defect candidate are avoided where possible. The further artificial intelligence 2 may also be integrated into the artificial intelligence 1 such that the functionality of the further artificial intelligence 2 is represented by the artificial intelligence 1.

Once the simulated defect candidates have been generated, the respective classification is subsequently queried from the user (step 150). In this case, the query is fundamentally analogous to the query of the classification of the identified defect candidates in step 130, and so reference is made to the explanations given there — especially also regarding the query at the level of defect groups into which the simulated defect candidates are combined. Before the defect candidates are displayed to the user, there is an additional step for the simulated defect candidates — the number of which is significantly higher than the number of identified defect candidates — in which the defect candidates that do not promise a learning effect for the artificial intelligence 1 are rejected such that the classification is not queried for these simulated defect candidates. For example, at this stage, the system may not know whether there will be a learning effect or not (for this, the actual classification would need to be known). However, it is possible to determine the likelihood that in case a defect candidate is classified one way or the other, the learning effect is big. For example, a defect candidate being very similar to an already classified defect candidate promises a lesser learning effect (likely the same classification, hardly any new features the AI could learn from) than a more distinct defect candidate. In this way, the number of simulated defect candidates to be classified by the user can be kept low, and rapid training of the artificial intelligence 1 can be ensured at the same time.

The artificial intelligence 1 may then be trained on the basis of the classified identified defect candidates and the classified simulated defect candidates — which may be considered to be training sets — such that it gradually matures into an artificial intelligence 1 which is able to classify, in an automated manner, a defect candidate classified by a user. The methods to this end are sufficiently well known for the various algorithms that are suitable for artificial intelligence 1 in the present case and do not require any further explanation. The same applies to the further artificial intelligence 2, which may likewise be suitably trained.

If, as in the present case, the identification of defect candidates on the aerial image (step 110) is also implemented with the aid of the artificial intelligence 1 (cf. method 112), then it is advantageous to carry out the identification of defect candidates on the aerial image (step 110) again once the training according to step 160 has been completed. Should additional defect candidates that have not been considered previously be identified in the process, the steps 120 to 160 may be run through again for these newly identified defect candidates. This ensures that as many defect candidates as possible can be identified on an aerial image.

In the illustrated exemplary embodiment, the artificial intelligences 1, 2 were initially trained using a user-unspecific and/or application-unspecific basic training data set so that the artificial intelligences 1, 2 can be used in the various steps 110, 120, 140 of the method 100 even during the first run through. A user-unspecific basic training date set refers to a basic training data set that is not specific to a particular user. An application-unspecific basic training data set refers to a basic training data set that is not specific to a particular application. In this case, however, the basic training data set is designed in terms of scope and form such that the training data contained therein no longer biases the artificial intelligences 1, 2 after only a few run-throughs of the method shown in FIG. 1. For example, defects of a specific class will come in different forms, sizes and varying degree of severeness. If the basic data set does not comprise any “extreme” defects, the training by the basic data set will soon matter much less than the actual training data.

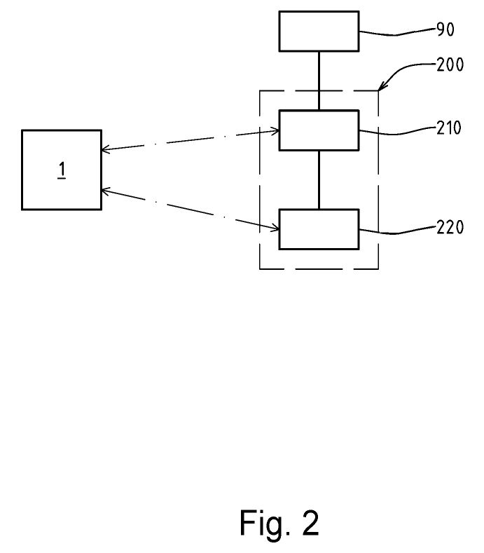

The artificial intelligence 1 is sufficiently trained for actual use after a sufficient number of run-throughs of the method 100 according to FIG. 1. For example, the number of run-throughs may be determined to be sufficient when the results produced by the artificial intelligence are sufficiently dependable. The corresponding method 200 is shown in FIG. 2.

In the method 200 for automated classification of defects on photolithographic masks on the basis of an aerial image of a photolithographic mask, an aerial image of a photolithographic mask to be analyzed is initially acquired with the aid of a suitable mask inspection device (step 90) before the actual method 200 is carried out. Since corresponding devices and acquisition methods are sufficiently well known in the prior art, explanations in this regard may be omitted here.

The acquired aerial image is supplied to the method 200, in which defect candidates on the aerial image are initially identified with the aid of the previously trained artificial intelligence 1. In this case step 210 is similar to step 110 of the method 100 according to FIG. 1, which is why reference is made to the explanations given there — also in view of alternative embodiment variants.

Then, the artificial intelligence 1 performs the classification for the defect candidates identified in this way (step 220). Since the artificial intelligence 1 was trained for precisely this application, the classification can be performed with a high degree of reliability.

The artificial intelligence 1 trained using the method 100 and used with the method 200 is distinguished in that it is trained in user-specific and/or application-specific fashion, i.e., the classification is performed according to the specifications of the user, possibly regarding specific types of structures on the photolithographic masks. For example, the applications may refer to the types of wafers to be produced, and an artificial intelligence model can be trained to process a particular type of wafer. In this context, the training method 100 in particular is distinguished in that, firstly, a manageable number of original defect candidates in acquired aerial images is sufficient to train the artificial intelligence 1 thanks to the defect candidates simulated on this basis and, secondly, the number of defect candidates actually to be classified by the user themselves remains manageable owing to the classification-specific rules for generating simulated defect candidates. This outlay may be reduced further by the optional combination of defect candidates and further measures of the possible measures described above. As a result, the training of an artificial intelligence 1 for the automated classification of defects on photolithographic masks in application-specific and/or user-specific fashion becomes practicable only by way of the method 100 according to the invention.

In some examples, a photolithography mask can be used to fabricate one layer of an integrated circuit that can include millions, tens of millions, hundreds of millions, billions, tens of billions, or hundreds of billions of transistors and other devices. The photolithography mask can be very complicated. When the photolithography mask is fabricated, there can initially be hundreds, thousands, tens of thousands or more of defects. For a user to individually assign a classification to each defect candidate one by one, it would take a tremendous amount of time to assign classifications to all of the defect candidates. Using the processes 100 or 200 described above, the artificial intelligence 1 and/or 2 can combine the defect candidates to form defect groups and each defect group can include tens, hundreds, thousands or more of defects. The system can query the user to assign a classification to each defect group.

For example, suppose there are ten thousand defect candidates numbered from 1 to 10000. Suppose there are 10 classifications, numbered from 1 to 10. The artificial intelligence 1 or 2 combines defect candidates 1 to 1000 to form defect group 1, combines defect candidates 1001 to 2500 to defect group 2, combines defect candidates 2501 to 3000 to form defect group 3, combines defect candidates 3001 to 4000 to form defect group 4, etc., to form defect groups 1 to 10. The system queries the user to assign a classification to each of defect groups 1 to 10 using the classifications 1 to 10. Instead of assigning classifications to 10000 defect candidates one by one, now the user only has to assign classifications to 10 defect groups. As a result, a tremendous amount of time can be saved in performing the task of assigning classifications to the defect candidates.

In some examples, there can be more than 20, 30, 40, 50, 60, 70, 80, 90, or 100 classifications. The process 100 and 200 can help the user to more consistently determine which one of the 20, 30, 40, 50, 60, 70, 80, 90, 100 or more classifications should be assigned to the defect candidates.

Suppose the number of defect candidates in a photolithographic mask is X1. Suppose using the process 100 or 200, the artificial intelligence 1 or artificial intelligence 2 combines the defect candidates to form defect groups, and the number of defect groups is X2. In some examples, X1 / X2 can be 10, 20, 30, 40, 50, 60, 70, 80, 90, 100, or greater. This means that by using the process 100 or 200, the number of assignment of classifications that need to be performed by the user can be reduced to 1/10, 1/20, 1/30, 1/40, 1/50, 1/60, 1/70, 1/80, 1/90, 1/100 or less compared to not using the process 100 or 200.

In some implementations, the processes described above, e.g., processes 100, 200, training of the artificial intelligence 1, 2, presentation of defects to the user for querying the user for classification of the defects, can be implemented by one or more computers (or computing devices), each computer can include one or more processor cores, and each processor core can include logic circuitry for processing data. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, each of the one or more computers can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage medium or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

A number of embodiments of the invention have been described. Nevertheless, it will be understood that various modifications may be made without departing from the spirit and scope of the invention.

What is claimed is:

1. A method for user-side training of an artificial intelligence for automated classification of defects on photolithographic masks on the basis of an aerial image of a photolithographic mask, including the steps of:
a) identifying defect candidates on the aerial image;
b) combining the identified defect candidates to form defect groups;
c) querying the classification of the defect candidates and/or defect groups from a user, for which purpose the defect candidates and/or at least one defect candidate representative of a defect group is displayed to the user;
d) generating simulated defect candidates by modifying the classified defect candidates according to rules that exist for a respective classification;
e) querying the classification of the simulated defect candidates from a user, for which purpose the defect candidates are displayed to the user; and
f) training the artificial intelligence using the classified defect candidates and classified simulated defect candidates for automated classification of a defect candidate not classified by a user.

2. The method of claim 1, wherein
defect candidates on the aerial image are identified by comparing the aerial image or a region of the aerial image with at least one of a previously captured aerial image, a region of a previously captured aerial image, a comparison image generated from the design data for the photolithographic mask, or a region of a comparison image generated from the design data for the photolithographic mask.

3. The method of claim 1, wherein
identification of defect candidates is supported or performed by the already at least partially trained artificial intelligence.

4. The method of claim 3, wherein
completion of the training of the artificial intelligence is followed by the identification of defect candidates on the aerial image being supported or performed by the previously trained artificial intelligence, and should new defect candidates be identified, steps (b) to (f) are performed for these new identified defect candidates.

5. The method of claim 1, wherein
the combination of the identified defect candidates to form defect groups is implemented by way of an automated image comparison and/or supported or performed by the already at least partially trained artificial intelligence.

6. The method of claim 1, wherein
the defect candidates are classified at the level of the defect groups, wherein defect candidates not matching the defect group can preferably be removed from the defect group by the user.

7. The method of claim 1, wherein
possible classifications are offered to the user when querying the classification, wherein the classifications offered preferably also comprise a classification which labels a defect candidate as not containing an actual defect.

8. The method of claim 1, wherein
the modification of classified defect candidates for the purpose of generating simulated defect candidates comprises image modification and/or motif manipulations.

9. The method of claim 1, wherein
the existing rules on which the generation of simulated defect candidates is based are adapted in view of the querying of the classification of simulated defect candidates from a user.

10. The method of claim 1, wherein
the simulated defect candidates are combined to form defect groups, the simulated defect candidates are displayed to the user in groups, and the classification of the simulated defect candidates is queried at the level of the defect groups, wherein simulated defect candidates not matching the defect group can preferably be removed from the defect group by the user.

11. The method of claim 1, wherein
the classification is not queried at least for simulated defect candidates which do not promise a learning effect for the artificial intelligence.

12. The method of claim 1, wherein
the artificial intelligence is initially trained using a user-unspecific and/or application-unspecific basic training data set.

13. The method of claim 1, wherein
the artificial intelligence is based on an algorithm for machine learning, preferably random decision forests or k-nearest neighbour, or an algorithm for deep learning, preferably convolutional neural networks or vision transformer networks.

14. A method for automatically classifying defects on photolithographic masks on the basis of an aerial image of a photolithographic mask, comprising the steps of:
a) identifying defect candidates on the aerial image; anda) using the artificial intelligence trained using the method of claim 1 to classify the identified defect candidates.

15. The method of claim 14, wherein
the identification of defect candidates on the aerial image is supported or performed by the artificial intelligence trained using the method of claim 1.

16. The method of claim 14, comprising identifying defect candidates on the aerial image by comparing the aerial image or a region of the aerial image with at least one of a previously captured aerial image, a region of a previously captured aerial image, a comparison image generated from the design data for the photolithographic mask, or a region of a comparison image generated from the design data for the photolithographic mask.

17. The method of claim 14, comprising identifying new defect candidates, and performing steps (b) to (f) for these new identified defect candidates.

18. The method of claim 14, comprising implementing the combining of the identified defect candidates to form defect groups by way of an automated image comparison and/or supported or performed by the trained artificial intelligence.

19. The method of claim 14, comprising classifying the defect candidates at the level of the defect groups.

20. The method of claim 14, comprising offering possible classifications to the user when querying the classification.
